(19) United States
(12) Patent Application Publication
(10) Pub. No.: US 2009/0108400 A1
(43) Pub. Date: Apr. 30, 2009

(54) ANTI-FUSE STRUCTURE INCLUDING A SENSE PAD CONTACT REGION AND METHODS FOR FABRICATION AND PROGRAMMING THEREOF

(75) Inventors: Alberto Cestero, Poughkeepsie, NY (US); Byeongju Park, Plainview, NY (US); John Safran, Wappingers Falls, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/931,167

(22) Filed: Oct. 31, 2007

(51) Int. Cl. H01L 23/58; H01L 21/441

(52) U.S. Cl. 257/530; 438/600; 257/E23.002; 257/E21.477

(57) ABSTRACT

An antifuse structure includes a sense pad contact region that is separate from an anode contact region and a cathode contact region. By including the sense pad contact region that is separate from the anode contact region and the cathode contact region, a programming current flow when programming the antifuse structure may travel a different pathway than a sense current flow when sensing the antifuse structure. In particular a sense current flow may avoid a depletion region created within the cathode contact region when programming the antifuse structure.

### BACKGROUND

1. Field of the Invention

The invention relates generally to antifuse structures within microelectronic structures. More particularly, the invention relates to enhanced performance antifuse structures for use within microelectronic structures.

2. Description of the Related Art

Microelectronic circuits include microelectronic devices, such as but not limited to semiconductor devices, that are formed within and/or upon a microelectronic substrate. The microelectronic devices are connected and interconnected over the microelectronic substrate while using patterned conductor layers that are separated by dielectric layers.

In addition to generally conventional microelectronic devices such as resistors, transistors, capacitors and diodes, microelectronic circuits also often include single use switching or selection devices such as fuses and antifuses. Fuses and antifuses within microelectronic circuits serve functions such as but not limited to microelectronic device or component trimming functions, and microelectronic device or component substitution functions.

While fuses and antifuses thus serve valuable functions within microelectronic circuits, fuses and antifuses are nonetheless not entirely without problems. In that regard, under circumstances where programming voltages or programming currents are either low or variable, a determination of whether a particular antifuse has been effectively programmed may be difficult.

Both fuse structures and antifuse structures are likely to be of continued prominence and importance as microelectronic structure and device technology, such as semiconductor structure and device technology, advances. To that end, desirable in particular are antifuse structures that allow for improved determination of effective programming of those antifuse structures under adverse programming conditions, as well as methods for fabricating such antifuse structures, and further as well as methods for effectively programming such antifuse structures.

### SUMMARY

The invention includes an antifuse structure, a method for fabricating the antifuse structure and a method for programming an antifuse within the antifuse structure. In particular, the antifuse structure includes a sense pad contact region that is separate from an anode contact region and a cathode contact region within the antifuse structure, where each of the sense pad contact region, the anode contact region and the cathode contact region is independently connected to an interconnect region (i.e., generally a single interconnect region) within the antifuse structure. Within the context of the invention, by separating the sense pad contact region from the anode contact region and the cathode contact region, an antifuse structure in accordance with the invention provides for a more reliable sensing of fusing of an antifuse within the antifuse structure since such a fusing determination is not limited to use of only an anode contact region and a cathode contact region that are also used when fusing the antifuse within the antifuse structure.

Within the context of the invention as described below, “a sense pad contact region that is separate from an anode contact region and a cathode contact region” is intended to exclude a linear arrangement of the sense pad contact region, the anode contact region and the cathode contact region. Rather, as disclosed above, each of the sense pad contact region, the anode contact region and the cathode contact region is intended to be connected to a single interconnect region in a fashion that provides for a programming current flow path that is different from a sense current flow path within the antifuse structure.

A particular antifuse structure in accordance with the invention includes an antifuse material layer located over a substrate and including a sense pad contact region that is separate from an anode contact region and a cathode contact region. The antifuse material layer also includes an interconnect region that interconnects the sense pad contact region, the anode contact region and the cathode contact region.

A particular method for fabricating an antifuse structure in accordance with the invention includes forming over a substrate an antifuse material layer that includes a sense pad contact region separate from an anode contact region and a cathode contact region, where the antifuse material layer also includes an interconnect region that interconnects the sense pad contact region, the anode contact region and the cathode contact region. This particular method also includes forming within the antifuse material layer a gap that separates the sense pad contact region and the cathode contact region from the anode contact region.

A particular method for programming an antifuse within an antifuse structure includes applying a programming current to an anode contact region and a cathode contact region within an antifuse structure that includes a sense pad contact region that is separate from the anode contact region and the cathode contact region, and where the anode contact region, the cathode contact region and sense pad contact region are interconnected with an interconnect region, to fuse the antifuse structure. This particular method also includes sensing the fused antifuse structure by applying a sensing current to the anode contact region and the sense pad contact region.

According to an embodiment of the present invention, an antifuse structure located on a substrate is provided. The antifuse structure comprises:

an anode contact region;

a cathode contact region separated from the anode contact region;

a sense pad contact region separated from the anode contact region and the cathode contact region; and

an interconnect region laterally abutting the anode contact region, the cathode contact region, and the sense pad contact region, wherein the antifuse structure comprises a vertical stack of a semiconductor material layer and a metal semiconductor alloy layer.

In one embodiment, each of the anode contact region, the cathode contact region, the sense pad contact region, and the interconnect region comprises a vertical stack of a conductive material layer portion and a metal semiconductor alloy portion.

In another embodiment, the metal semiconductor alloy layer comprises a first metal semiconductor alloy portion laterally abutting the cathode contact region and the sense pad contact region and a second metal semiconductor alloy portion laterally abutting the anode contact region, and wherein the first metal semiconductor alloy portion and the second metal semiconductor alloy region are separated by a gap.

In even another embodiment, the metal semiconductor alloy layer comprises a metal semiconductor alloy containing a semiconductor material selected from the group consisting of silicon, germanium and silicon-germanium alloy semiconductor materials.

In yet another embodiment, the interconnect region comprises a first interconnect region portion laterally abutting the anode contact region and the cathode contact region and a second interconnect region portion laterally abutting the sense pad contact region and the first interconnect region.

In still another embodiment, the first interconnect region portion comprises a stack of a contiguous semiconductor material layer portion and two disjoined metal semiconductor alloy layer portions separated by a gap.

In a further embodiment, the second interconnect region portion comprises a stack of another contiguous semiconductor material layer portion and another metal semiconductor alloy portion, each laterally abutting the sense pad contact region and the first interconnect region.

According to another aspect of the present invention, a method for fabricating a microelectronic structure is provided. The method comprises:

forming, over a substrate, a vertical stack of a semiconductor material layer and a metal semiconductor alloy layer, the stack containing:
an anode contact region;
a cathode contact region separated from the anode contact region;
a sense pad contact region separated from the anode contact region and the cathode contact region; and
an interconnect region laterally abutting the anode contact region, the cathode contact region, and the sense pad contact region; and

forming within the metal semiconductor alloy layer a gap that separates the sense pad contact region and the cathode contact region from the anode contact region.

In one embodiment, the metal semiconductor alloy layer comprises a first metal semiconductor alloy portion laterally abutting the cathode contact region and the sense pad contact region and a second metal semiconductor alloy portion laterally abutting the, anode contact region, and wherein the first metal semiconductor alloy portion and the second metal semiconductor alloy region are separated by the gap.

In another embodiment, the interconnect region comprises a first interconnect region portion laterally abutting the anode contact region and the cathode contact region and a second interconnect region portion laterally abutting the sense pad contact region and the first interconnect region.

In even another embodiment, the first interconnect region portion comprises a stack of a contiguous semiconductor material layer portion and two disjoined metal semiconductor alloy layer portions separated by the gap.

In yet another embodiment, the second interconnect region portion comprises a stack of another contiguous semiconductor material layer portion and another metal semiconductor alloy portion, each laterally abutting the sense pad contact region and the first interconnect region.

In still another embodiment, the metal-semiconductor antifuse material layer is formed using a salicide method.

In still yet another embodiment, the forming the antifuse material layer and the forming the gap occur simultaneously.

In a further embodiment, the forming the antifuse material layer and the forming the gap do not occur simultaneously.

In an even further embodiment, the method further comprises masking an area of the gap with a masking layer formed directly on the semiconductor material layer prior to formation of the metal semiconductor layer.

In a yet further embodiment, the forming the gap uses an ablation method.

According to yet another aspect of the present invention, a method for operating an antifuse is provided, which comprises:

providing an antifuse comprising:
an anode contact region;
a cathode contact region separated from the anode contact region;
a sense pad contact region separated from the anode contact region and the cathode contact region; and
an interconnect region laterally abutting the anode contact region, the cathode contact region, and the sense pad contact region;

programming the antifuse by applying a programming current between the anode and cathode and by inducing electromigration in the interconnect region; and

sensing a resistance between the anode contact region and the cathode contact region.

In one embodiment, the resistance decreases upon the programming of the antifuse.

In another embodiment, the antifuse structure comprises a vertical stack of a semiconductor material layer and a metal semiconductor alloy layer, and wherein each of the anode contact region, the cathode contact region, the sense pad contact region, and the interconnect region comprises a stack of a conductive material layer portion and a metal semiconductor alloy portion.

In even another embodiment, the metal semiconductor alloy layer comprises a first metal semiconductor alloy portion laterally abutting the cathode contact region and the sense pad contact region and a second metal semiconductor alloy portion laterally abutting the, anode contact region, and wherein the first metal semiconductor alloy portion and the second metal semiconductor alloy region are separated by a gap.

In yet another embodiment, the gap is filled with an electromigrated material which is compositionally substantially the same as the metal semiconductor alloy layer during the programming of the antifuse.

In even another embodiment, a portion of the metal semiconductor alloy layer is depleted from the cathode contact portion during the programming of the antifuse, wherein a remaining portion of the metal semiconductor alloy layer in the cathode contact portion is disconnected from the interconnect region.

### BRIEF DESCRIPTION OF THE DRAWINGS

The objects features and advantages of the invention are understood within the context of the Description of the Preferred Embodiment, as set forth below. The Description of the Preferred Embodiment is understood within the context of the accompanying drawings, which form a material part of this disclosure, wherein:

FIG. 1A to FIG. 6B show a series of schematic plan-view and schematic cross-sectional diagrams illustrating the results of progressive stages in fabricating an antifuse structure in accordance with a particular embodiment of the invention, and then programming an antifuse within the antifuse structure in accordance with the particular embodiment of the invention.

### DESCRIPTION OF THE PREFERRED EMBODIMENT

The invention, which includes an antifuse structure, a method for fabricating the antifuse structure and a method for programming an antifuse within the antifuse structure, is understood within the context of the description set forth below. The description set forth below is understood within the context of the drawings described above. Since the drawings are intended for illustrative purposes, the drawings are not necessarily drawn to scale.

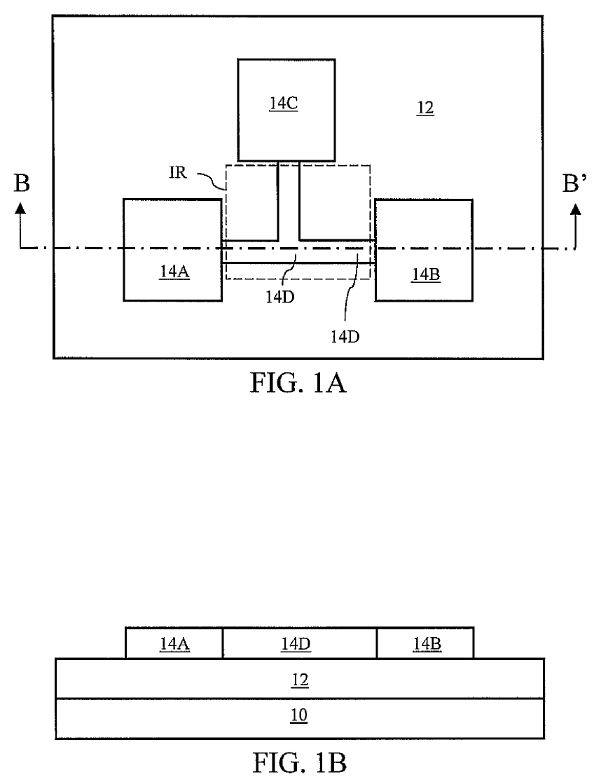

FIG. 1A to FIG. 6B show a series of schematic plan-view and schematic cross-sectional diagrams illustrating the results of progressive stages in fabricating an antifuse structure and then programming an antifuse within the antifuse structure, in accordance within a particular embodiment of the invention. This particular embodiment of the invention comprises a sole preferred embodiment of the invention.

FIG. 1A and FIG. 1B show, respectively, a schematic plan-view diagram and a corresponding schematic cross-sectional diagram illustrating the antifuse structure at an early stage in the fabrication thereof and the programming thereof in accordance with this particular sole preferred embodiment.

FIG. 1A shows in a schematic plan-view diagram a semiconductor material layer (i.e., 14A-14D in an aggregate) that is located and formed upon a dielectric layer 12. FIG. 1B further shows in a corresponding schematic cross-sectional diagram a substrate 10 upon which is located and formed the dielectric layer 12.

The substrate 10 may comprise any of several substrate materials, including but not limited to conductor materials, semiconductor materials and dielectric materials. Conductor materials are less common materials of composition of the substrate 10, although they are nonetheless known. Semiconductor materials are generally more common. Finally, dielectric materials are also generally more common materials from which may be comprised the substrate 10, and under certain circumstances where the substrate 10 comprises a dielectric material, the dielectric layer 12 may be optional within the instant embodiment.

The substrate 10 when comprised of a semiconductor material may comprise any of several semiconductor materials. Non-limiting examples include silicon, germanium, silicon-germanium alloy, silicon-carbon alloy, silicon-germanium-carbon alloy and compound (i.e., III-V and II-VI) semiconductor materials. Non-limiting examples of compound semiconductor materials include gallium arsenide, indium arsenide and indium phosphide semiconductor materials.

The substrate 10 when comprised of a dielectric material may also comprise any of several dielectric materials. Non-limiting examples include silica, titania, alumina and zirconia dielectric materials that may provide the substrate 10 as a glass substrate, a ceramic substrate or a glass-ceramic alloy substrate.

Within the context of any of the foregoing materials of composition for the substrate 10, the substrate 10 will typically have a thickness from about 1 to about 3 millimeters. In addition, and in particular when the substrate 10 comprises a semiconductor material, such a semiconductor substrate will typically and preferably have included therein and/or thereupon semiconductor devices that are otherwise generally conventional in the semiconductor fabrication art. Generally included, but also not limiting, are semiconductor devices such as but not limited to transistors and diodes, as well as microelectronic devices which need not necessarily be semiconductor devices, such as but not limited to resistors and capacitors.

The dielectric layer 12 may comprise any of several dielectric materials. Non-limiting examples include oxides, nitrides and oxynitrides, particularly of silicon, but oxides, nitrides and oxynitrides of other elements are not excluded. The dielectric layer 12 may comprise a crystalline or a non-crystalline dielectric material, with crystalline dielectric materials under certain circumstances being highly preferred. The dielectric layer 12 may also be formed using any of several methods. Non-limiting examples include ion implantation methods, thermal or plasma oxidation or nitridation methods, chemical vapor deposition methods and physical vapor deposition methods. Typically, the dielectric layer 12 comprises a dielectric material such as a dielectric oxide or a dielectric nitride. The dielectric oxide may be an oxide of a semiconductor material or a ceramic oxide. The dielectric layer 12 may be a patterned structure such as a shallow trench isolation structure typically employed as insulating structures between adjacent devices on a semiconductor substrate. Preferably, the dielectric layer 12 is thick enough to provide sufficient thermal isolation of an antifuse structure to be subsequently formed over the substrate 10. The dielectric layer 12 may have a thickness from about 1 nm to about 10 μm, and typically from about 100 nm to 500 nm. Preferably, the dielectric layer 12 comprises at least in-part an isolation region that is located at least in part within a semiconductor substrate that comprises at least in-part the substrate 10.

Although the instant embodiment thus illustrates the invention at least in-part within the context of a semiconductor structure that may include a bulk semiconductor substrate as the substrate 10, neither the embodiment, nor the invention, is intended to be so limited. Rather, the present invention may alternatively be practiced using as a substrate 10 a semiconductor-on-insulator substrate that would otherwise result from addition of a buried dielectric layer interposed between a base semiconductor substrate portion and a surface semiconductor layer portion of the substrate 10 when is comprised of a semiconductor material. The embodiment also contemplates for use as the substrate 10 a hybrid orientation (HOT) substrate that has multiple crystallographic orientation regions supported by a single semiconductor substrate.

Within the context of the instant embodiment, and while not intending to limit the embodiment or the invention, the semiconductor material layer comprises a semiconductor material from which may be formed a metal semiconductor alloy layer that in turn serves as an antifuse layer (i.e., an antifuse material layer) incident to further processing of the antifuse structure whose schematic plan-view and schematic cross-sectional diagrams are illustrated in FIG. 1A and FIG. 1B. Although also not a limitation of the embodiment or the invention, such a metal semiconductor alloy layer may be formed using an otherwise generally conventional salicide method that is described in greater detail below. From a practical perspective, such a semiconductor material from which may be formed a metal semiconductor alloy layer is generally limited to a semiconductor material selected from the group including but not limited to silicon semiconductor materials, germanium semiconductor materials and silicon-germanium alloy semiconductor materials. Such silicon semiconductor materials, germanium semiconductor materials or silicon-germanium alloy semiconductor materials may be provided and present as monocrystalline semiconductor materials, polycrystalline semiconductor materials or amorphous semiconductor materials. The semiconductor material layer may comprise a polysilicon material that has a thickness from about 20 nm to about 300 nm, and typically from about 50 nm to about 150 nm. The semiconductor layer 14 may be doped or substantially undoped.

As is finally illustrated within the schematic plan-view diagram of FIG. 1A, the semiconductor material layer includes a cathode semiconductor portion 14A, an anode semiconductor portion 14B, and a sense pad semiconductor region 14C, as well as an interconnect semiconductor portion 14D that connects and interconnects the cathode semiconductor portion 14A, the anode semiconductor portion 14B, and the sense pad semiconductor portion 14C. The foregoing four semiconductor portions (14A-14D) are sized in aerial dimensions otherwise generally conventionally. The areal region containing the interconnect semiconductor portion 14D is herein referred to as an interconnect region IR. Preferably, the interconnect semiconductor portion 14D is printed at or close to the lithographically printable minimum dimension, or a “critical dimension,” which is the smallest dimension that is printable with lithographic tools at a given technology generation. As of 2007, the lithographically printable minimum dimension is from about 30 nm to about 65 nm depending on the lithography tools employed. Paraphrased, it is preferred that the width of the IR be from about 30 nm to about 65 nm, or even smaller if lithographic tools capable of printing such smaller dimensions become available.

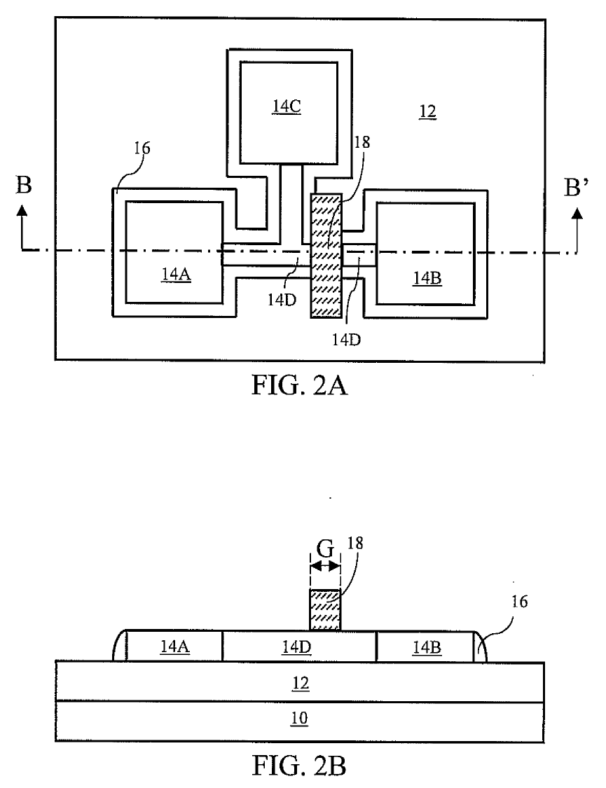

FIG. 2A and FIG. 2B first show a spacer 16 that is located and formed adjacent and adjoining the sidewalls of the semiconductor material layer (14A-14D). Spacers may in general be formed using materials including but not limited to conductor materials, semiconductor materials and dielectric materials, although spacers in general, and the spacer 16 more particularly, typically comprises a dielectric material. Suitable selections for such a dielectric material include oxides, nitrides and oxynitrides of silicon, although oxides, nitrides and oxynitrides of other elements are not excluded.

The spacer 16 may be formed using methods that are otherwise generally conventional in the microelectronic fabrication art. Typically, the spacer 16 is formed with the distinctively inward pointed tapered spacer shape while using a blanket layer deposition method followed by an anisotropic plasma etch method. Typically, the spacer 16 comprises a silicon oxide dielectric material that completely encircles the semiconductor material layer (14A-14D).

FIG. 2A and FIG. 2B also show a masking layer 18 located and formed upon a portion of the semiconductor material layer (14A-14D). As is illustrated in particular within the context of the schematic plan-view diagram of FIG. 2A, the masking layer 18 is located and formed in a particular position such that the masking layer 18 traverses a portion of the interconnect semiconductor portion 14D of the semiconductor material layer (14A-14D), leaving only the anode semiconductor portion 14B on the right hand side of the masking layer 18 and both the cathode semiconductor portion 14A and the sense pad semiconductor portion 14C to the left hand side of the masking layer 18.

The masking layer 18 may comprise any of several masking materials. Within the context of further description that follows, the masking layer 18 comprises a thermally stable masking material that may be used as a metal-semiconductor blocking material. As a result of this requirement, the masking layer 18 typically comprises a dielectric masking material. Suitable dielectric masking materials include, but are not necessarily limited to silicon oxide, silicon nitride and silicon oxynitride masking materials. Oxides, nitrides and oxynitrides of other elements are not excluded as suitable masking materials for forming the masking layer 18. Typically, the masking layer 18 comprises a silicon nitride masking material that has a thickness from about 10 nm to about 200 nm, and typically from about 30 nm to about 100 nm, although lesser and greater thicknesses are explicitly contemplated herein also. Desirably, the masking layer 18 and the spacer 16 comprise different materials in order to provide etch selectivity of the masking layer 18 with respect to the spacer 16 in accordance with further processing of the microelectronic structure of FIG. 2A and FIG. 2B.

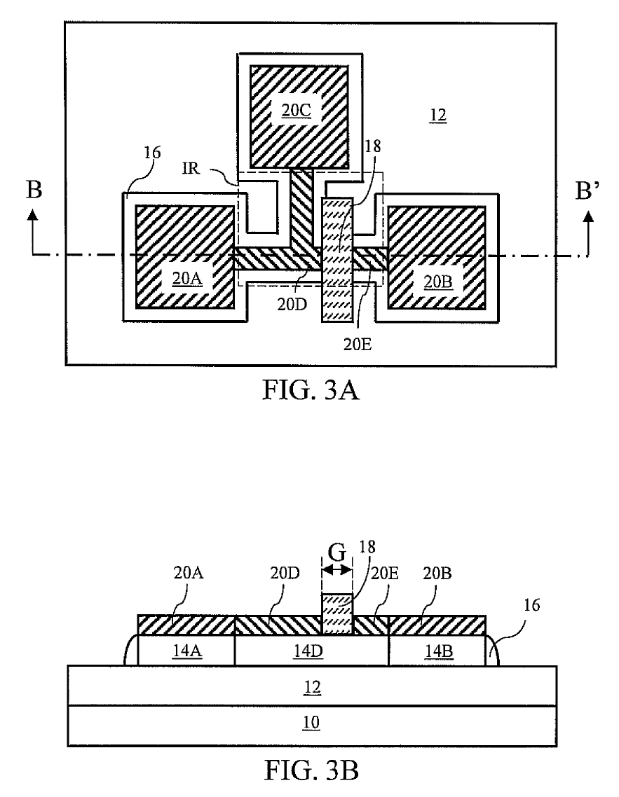

FIG. 3A and FIG. 3B show a metal semiconductor alloy layer (20A-20E) located and formed upon the semiconductor material layer (14A-14D). The metal semiconductor alloy layer is derived from the semiconductor material layer (14A-14D). The metal semiconductor alloy layer comprises a cathode metal semiconductor alloy portion 20A, an anode metal semiconductor alloy portion 20B, a sense pad metal semiconductor alloy portion 20C, a first interconnect metal semiconductor alloy portion 20D, and a second metal semiconductor alloy portion 20E. The first and second interconnect metal semiconductor alloy portions vertically abut the interconnect semiconductor portion 14D, are located within the interconnect region IR, and are separated from each other by the gap G.

The metal semiconductor alloy layer (20A-20E) is typically formed using a salicide type method. The salicide type method includes: (1) forming a metal-semiconductor (i.e., typically metal-silicide) forming metal layer upon the microelectronic structure of FIG. 2A and FIG. 2B; (2) thermally annealing the microelectronic structure including the metal-semiconductor forming metal layer and the semiconductor material (i.e., semiconductor material layer (14A-14D)) which contact the metal-semiconductor forming metal layer to form the metal semiconductor alloy layer (20A-20E); and (3) stripping excess metal-semiconductor forming metal from the resulting microelectronic structure while leaving remaining the metal semiconductor alloy layer (20A-20E).

Candidate metal-semiconductor forming metals for forming the metal semiconductor alloy layer (20A-20E) include nickel, cobalt, titanium, tantalum, tungsten and vanadium metal-semiconductor forming metals. As is illustrated within the schematic cross-sectional diagram of FIG. 3A and FIG. 3B, due to the presence of the mask layer 18, the metal semiconductor alloy layer (20A-20E), which is typically formed to a thickness from about 10 nm to about 50 nm, is not formed completely covering the semiconductor material layer (14A-14D), but rather is blocked within the interconnect region IR at a location that separates the first interconnect metal semiconductor alloy portion 20D from the second metal semiconductor alloy portion 20E.

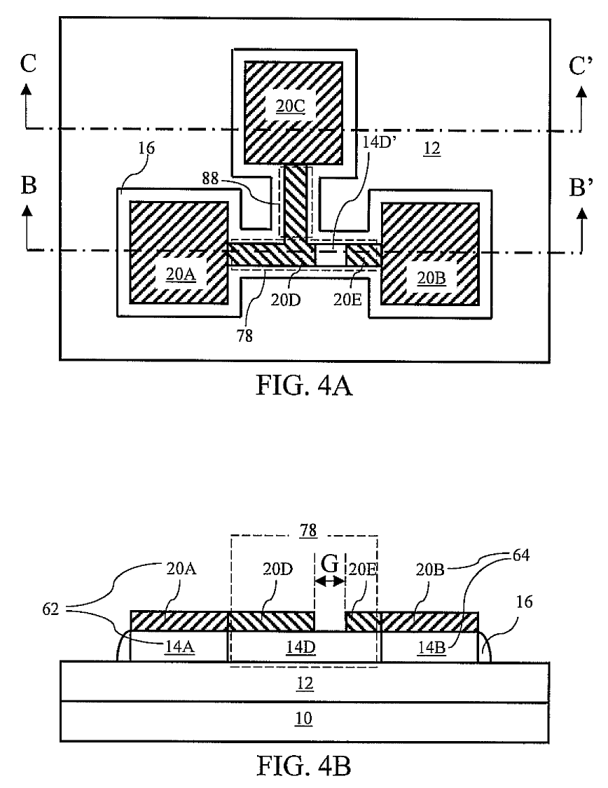

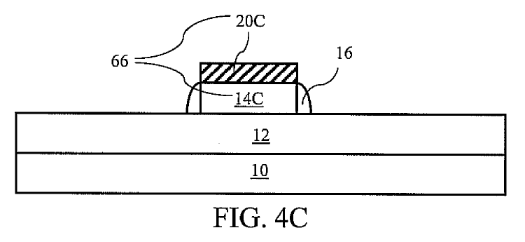

FIGS. 4A-4C show the results of stripping the masking layer 18 from the microelectronic structure of FIG. 3A and FIG. 3B to leave remaining a gap G that exposes the interconnect semiconductor portion 14D, as illustrated by the phantom box designated by reference numeral 78. Preferably, the gap G is as small as possible. In this case, the dimension of the gap G is determined by technological limits of methods employed for forming the gap G. In this case, the minimum lateral dimension of the masking layer 18 determines the separation distance of the gap G, which may be from about 30 nm to about 150 nm. In general, the masking layer 18 may be stripped using methods and materials that are otherwise generally conventional in the microelectronic fabrication art. Such methods may include, but are not necessarily limited to, wet chemical etch methods, dry plasma etch methods and combinations of wet chemical etch methods and dry plasma etch methods. Under circumstances in particular where the masking layer 18 comprises a silicon nitride material, the masking layer 18 may be stripped selectively with respect to the metal semiconductor alloy layer (20A-20E), the spacer 16 and the dielectric layer 12 while using an aqueous phosphoric acid etching solution at an elevated temperature.

The cathode semiconductor region 14A and the cathode metal semiconductor portion 20A collectively constitute a cathode contact region 62. The anode semiconductor region 14B and the anode metal semiconductor portion 20B collectively constitute an anode contact region 64. The sense pad semiconductor region 14C and the sense metal semiconductor portion 20C collectively constitute a sense pad contact region 66. The interconnect semiconductor portion 14D, the first interconnect metal semiconductor alloy portion 20D, and the second interconnect metal semiconductor alloy portion 20E collectively constitute the interconnect region IR.

In another perspective, the interconnect region IR comprises a first interconnect region portion 78 and a second interconnect region portion 88. The first interconnect region portion 78 laterally abutting the anode contact region 64 and the cathode contact region 62 and a second interconnect region portion 88 laterally abutting the sense pad contact region 66 and the first interconnect region 78.

While the preferred embodiment illustrates the invention within the context of the gap G that is formed using a masking method, as an alternative the gap G may also be formed using an ablative method, such as a laser ablative method, with respect to a metal semiconductor alloy layer that completely covers the semiconductor material layer (14A-14D). Thus, the gap G may be formed simultaneously with forming the metal semiconductor alloy layer (20A-20E) or after forming a blanket metal semiconductor alloy layer that serves as a precursor layer to the metal semiconductor alloy layer (20A-20E).

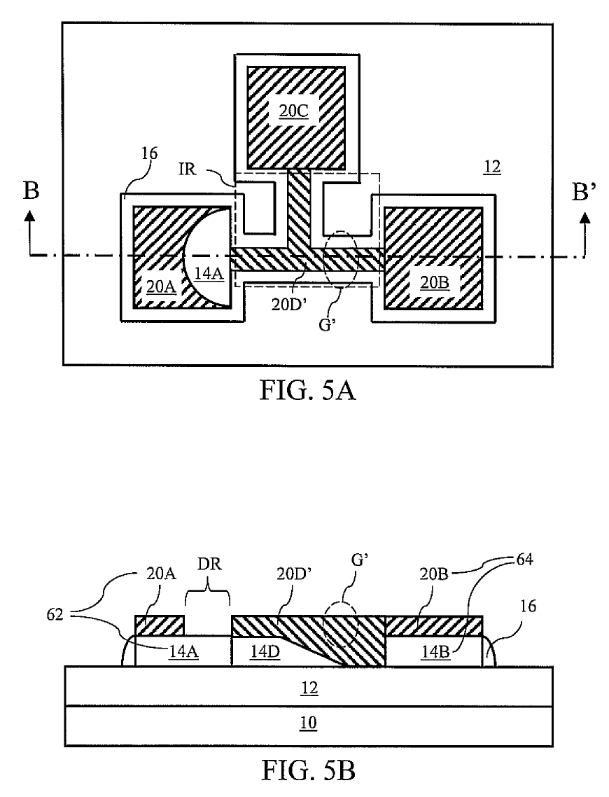

FIG. 5A and FIG. 5B show the results of programming the antifuse structure that is illustrated within the schematic plan-view and schematic cross-sectional diagrams of FIG. 4A and FIG. 4B. The programming of the antifuse structure of FIG. 4A and FIG. 4B is effected by applying a programming current Ipr with respect to the anode contact region 64 and the cathode contact region 62. Typically, the programming current Ipr is in a range from about 1 mA to about 20 mA at a programming voltage from about 1.0 V to about 5.0 V. As a result of such programming of the antifuse structure, the first and second metal semiconductor alloy portions (20D, 20E) that serves as an antifuse material layer, is fused to form an electromigrated metal semiconductor alloy portion 20D′ comprising two joined portions. As a result of such fusing, i.e., electromigrating, of the first and second metal semiconductor alloy portions (20D, 20E) to form the electromigrated metal semiconductor alloy portion 20D′, the gap G that is illustrated within FIG. 3A and FIG. 3B is backfilled with metal semiconductor alloy that migrates from an inward edge of the cathode metal semiconductor alloy portion 20A at a junction of the cathode contact region 62 with the interconnect region IR into the interconnect region IR to form a backfilled gap G′ within the interconnect region IR.

Typically, the electromigrated metal semiconductor alloy portion 20D′ diffuses downward and contacts the dielectric layer 12. Thus, the interconnect semiconductor portion 14D is separated from the anode semiconductor portion 14B by the electromigrated metal semiconductor alloy portion 20D′. The electromigrated metal semiconductor alloy portion 20D′ comprises substantially the same material as the metal semiconductor alloy layer (20A-20D), in which any difference in composition is caused by admixture or alloying of the electromigrated metal semiconductor alloy material with the semiconductor material.

As a further result of the foregoing electromigration fusing, or electromigrating, of the first and second interconnect metal semiconductor alloy portions (20D, 20E) to form the electromigrated metal semiconductor alloy portion 20D′ that backfills the gap G to form the backfilled gap G′, a depleted region DR located within the cathode contact region is formed, which extends inward from the junction with the interconnect region IR.

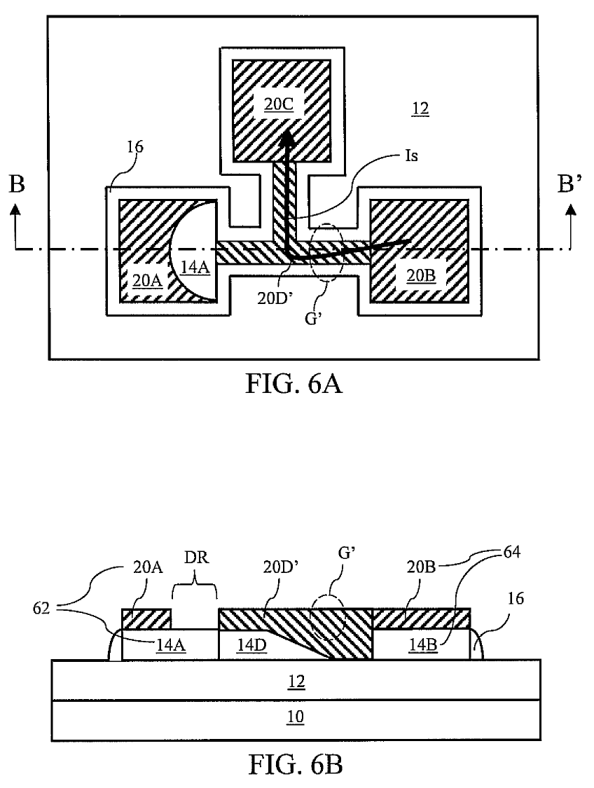

FIG. 6A and FIG. 6B show a sense current Is applied between the sense pad contact region 66 and the anode contact region 64. Such a sense current Is is typically in a range from about 1 μA to about 1 mA at a sense voltage from about 0.05 V to about 1.5 V. As is illustrated within the schematic plan-view and schematic cross-sectional diagrams of FIG. 6A and FIG. 6B, the sense current Is between the sense pad contact region 66 and the anode contact region 64 passes through the electromigrated metal semiconductor alloy portion 20D′, which has a lower resistance than the portion of the interconnect semiconductor portion 14D underneath the gap G prior to programming.

The reduction in the resistance is then interpreted as a programmed state of the antifuse structure. Conversely, if no reduction in the resistance is measured, the state of the antifuse is interpreted as unprogrammed, i.e., intact having the same structure shown in FIGS. 4A-4C.

FIG. 6A and FIG. 6B show a schematic plan-view diagram and a schematic cross-sectional diagram of a fused antifuse structure in accordance with a sole preferred embodiment of the invention. Such an antifuse structure includes a sense pad contact region 66 that is separate from an anode contact region 64 and a cathode contact region 62, all of which are interconnected by an interconnect region IR within the antifuse structure. By using such a separate sense pad contact region 66, an adequate fusing of the antifuse structure may be reliably discerned insofar as the presence of the sense pad contact region 66 provides for the presence and use of a programming current pathway within the antifuse structure that is different from a sense current pathway within the antifuse structure. In particular, within the instant embodiment, a programming current Ipr is applied between an anode contact region 64 and a cathode contact region 62, and as a result of the programming current a depletion region DR is formed within the cathode contact region 62. Since a sense current Is is applied between the anode contact region 64 and the sense pad contact region 66, the sense current does not pass through the depletion region DR. Similarly, since the depletion region DR may yield a considerable thinning of a metal semiconductor layer (20A-20D) and a consequent resistance increase in the within the cathode contact region 62, by not passing through the depletion region DR a sense current Is may be more reliably and accurately sensed.

Thus, the sensing of the state of the antifuse structure is facilitated by measurement of resistance between the anode contact region 64 and the sense pad contact region 66. In an unprogrammed antifuse structure, which is an intact antifuse structure having the same structure as the antifuse structure prior to programming as shown in FIGS. 2A and 2B, the resistive path between the anode contact region 64 and the sense pad contact region 66 includes a portion of the interconnect semiconductor portion 14D.

Since the interconnect semiconductor portion 14D contains a semiconductor material, which has a higher resistivity even in the most heavily doped state compared with any metal semiconductor alloy, an unprogrammed antifuse structure displays a higher resistance between the anode contact region 64 and the sense pad contact region 66 than a programmed antifuse structure containing an electromigrated metal semiconductor alloy portion 20D′ as shown in FIGS. 5A, 5B, 6A, and 5B. By measuring the resistance between the anode contact region 64 and the sense pad contact region 66, the status of the antifuse, i.e., whether the antifuse structure has been programmed or not, may be readily ascertained. Since the difference in resistivity of a doped semiconductor material and a metal semiconductor alloy is a few orders of magnitude, detection of the status of the antifuse structure by sensing the resistance between the anode contact region 64 and the sense pad contact region 66 is a relative easy circuit operation, requiring a simple sensing circuit. Thus, the present invention provides a compact antifuse structure that may be sensed by a compact sensing circuit.

The preferred embodiment is illustrative of the invention rather than limiting of the invention. Revisions and modifications may be made to methods, materials, structures and dimensions of an antifuse structure in accordance with the preferred embodiment of the invention, while still providing an antifuse structure in accordance with the invention, further in accordance with the accompanying claims.

1-20. (canceled)

21. A method for fabricating a microelectronic structure comprising:
forming, over a substrate, a vertical stack of a semiconductor material layer and a metal semiconductor alloy layer, said stack containing:
an anode contact region;
a cathode contact region separated from said anode contact region;
a sense pad contact region separated from said anode contact region and said cathode contact region; and
an interconnect region laterally abutting said anode contact region, said cathode contact region, and said sense pad contact region; and
forming by laser ablation within said metal semiconductor alloy layer a gap that separates said sense pad contact region and said cathode contact region from said anode contact region, wherein said metal semiconductor alloy layer comprises a first metal semiconductor alloy portion laterally abutting said cathode contact region and said sense pad contact region and a second metal semiconductor alloy portion laterally abutting said anode contact region, said first metal semiconductor alloy portion and said second metal semiconductor alloy region are separated by said gap, said interconnect region comprises a first interconnect region portion laterally abutting said anode contact region and said cathode contact region and a second interconnect region portion laterally abutting said sense pad contact region and said first interconnect region, said first interconnect region portion comprises a stack of a contiguous semiconductor material layer portion and two disjoined metal semiconductor alloy layer portions separated by said gap, and said second interconnect region portion comprises a stack of another contiguous semiconductor material layer portion and another metal semiconductor alloy portion, each laterally abutting said sense pad contact region and said first interconnect region.
